(19) United States
(12) Patent Application Publication
(10) Pub. No.: US 2025/0077750 A1
(43) Pub. Date: Mar. 6, 2025

(54) MACRO MODEL, CIRCUIT DESIGN SIMULATION PROGRAM INCLUDING MACRO MODEL AND CIRCUIT DESIGN SIMULATOR CAPABLE OF EXECUTING CIRCUIT DESIGN SIMULATION PROGRAM

(71) Applicant: ROHM CO., LTD., Kyoto (JP)

(72) Inventor: Katsuyuki ONO, Kyoto (JP)

(21) Appl. No.: 18/819,399

(22) Filed: Aug. 29, 2024

(30) Foreign Application Priority Data
Aug. 31, 2023 (JP) 2023-140863

(51) Int. Cl. G06F 30/327; G06F 30/3308

(52) U.S. Cl. CPC G06F 30/327; G06F 30/3308

(57) ABSTRACT

A macro model is used in a circuit design simulator based on a nodal method. The macro model is configured to include a behavior model the function of which is defined by one conditional branch that includes a plurality of conditional branches as options.

### INCORPORATION BY REFERENCE

This nonprovisional application claims priority under 35 U.S.C. § 119 (a) on Patent Application No. 2023-140863 filed in Japan on Aug. 31, 2023, the entire contents of which are hereby incorporated by reference.

### BACKGROUND OF THE DISCLOSURE

### Field of the Invention

The present disclosure relates to a macro model, a circuit design simulation program which includes a macro model and a circuit design simulator capable of executing a circuit design simulation program.

### Description of the Related Art

In general, a macro model is known as a model for circuit design simulation which combines a plurality of behavior models to simulate the response of a circuit using a nodal method.

### SUMMARY OF THE DISCLOSURE

A macro model disclosed in the present specification is used in a circuit design simulator based on a nodal method. The macro model is configured to include a behavior model the function of which is defined by one conditional branch that includes a plurality of conditional branches as options.

A circuit design simulation program disclosed in the present specification is a circuit design simulation program configured to be executed by a computer including a computation unit and to cause the computer to function as the circuit design simulator. The circuit design simulation program includes the macro model configured as described above, and operates the computer such that the response of a semiconductor integrated circuit device is simulated on the circuit design simulator.

A circuit design simulator disclosed in the present specification is realized by causing the computer to execute the circuit design simulation program configured as described above.

In the macro model disclosed in the present specification, it is possible to suppress the occurrence of the convergence problem of a calculation result.

In the circuit design simulation program disclosed in the present specification, it is possible to provide the circuit design simulation program which can suppress the occurrence of the convergence problem of a calculation result.

In the circuit design simulator disclosed in the present specification, it is possible to provide the circuit design simulator which can suppress the occurrence of the convergence problem of a calculation result.

### DESCRIPTION OF THE DRAWINGS

FIG. 1 is a block diagram showing an internal configuration of a semiconductor integrated circuit device;

FIG. 2 is a circuit diagram showing the configuration of the semiconductor integrated circuit device;

FIG. 3 is a block diagram showing the configuration of a conventional macro model;

FIG. 4 is a block diagram showing the configuration of the macro model of the present disclosure;

FIG. 5 is a block diagram showing a configuration example of a circuit design simulator using the macro model of the present disclosure; and

FIG. 6 is a diagram showing a configuration example of a circuit design simulation program.

### DESCRIPTION OF THE PREFERRED EMBODIMENTS

### <Component Serving as Simulation Target>

A semiconductor integrated circuit device 2 which is a simulation target for the macro model X of the present disclosure and the macro model Y of a comparison target will first be described. Here, a description will be given using an operational amplifier as an example of the semiconductor integrated circuit device 2.

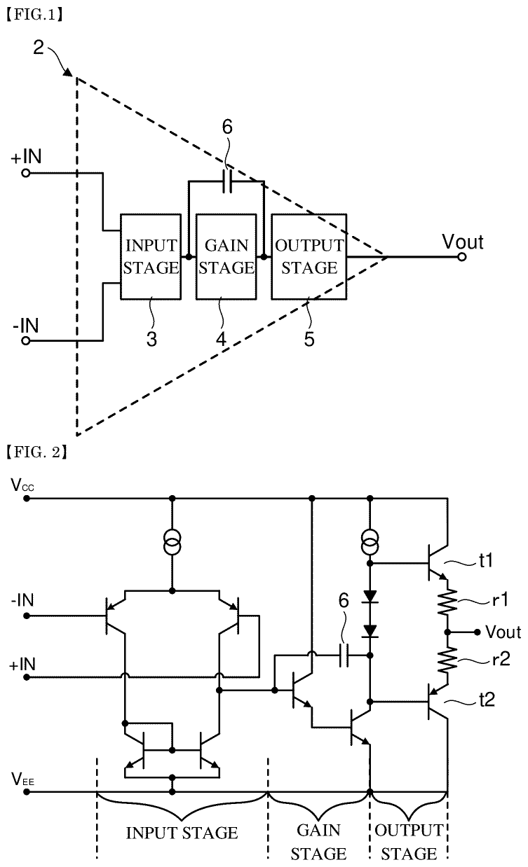

FIG. 1 is a block diagram showing an internal configuration of the semiconductor integrated circuit device 2. As shown in FIG. 1, the semiconductor integrated circuit device 2 includes an input stage 3, a gain stage 4, an output stage 5 and a phase compensation capacitor 6.

The input stage 3 includes an inverting input terminal (+) and a non-inverting input terminal (−). The gain stage 4 is connected between the input stage 3 and the output stage 5. The first end of the phase compensation capacitor 6 is connected to the input end of the gain stage 4. The second end of the phase compensation capacitor 6 is connected to the output end of the gain stage 4. The phase compensation capacitor 6 prevents oscillation of the semiconductor integrated circuit device 2.

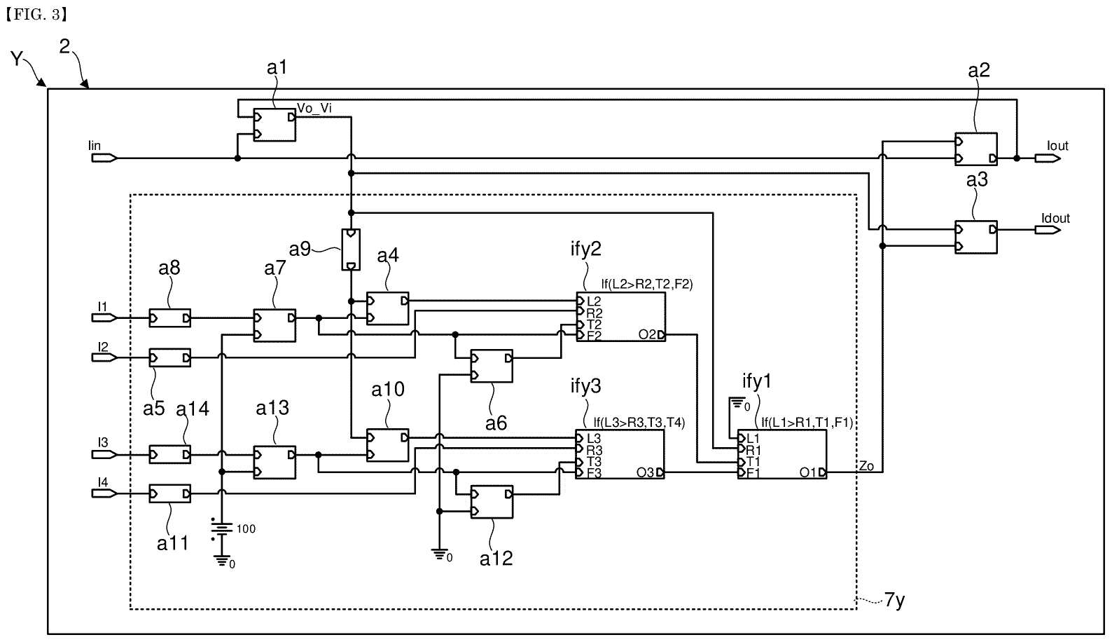

FIG. 2 is a circuit diagram showing the configuration of the semiconductor integrated circuit device 2. As shown in FIG. 2, the input stage 3 includes a PNP bipolar transistor in which its base is connected to the non-inverting input terminal (+) and a PNP bipolar transistor in which its base is connected to the inverting input terminal (−). The input stage 3 generates an internal signal by amplifying a differential voltage between the non-inverting input terminal (+) and the inverting input terminal (−), and inputs the internal signal to the gain stage 4.

The gain stage 4 receives the internal signal from the input stage 3 to generate a high-side signal and a low-side signal. The high-side signal is input to the base of a transistor t1 which will be described later. The low-side signal is input to the base of a transistor t2 which will be described later.

The output stage 5 includes the transistors t1 and t2 and resistors r1 and r2. The transistor t1 is an NPN bipolar transistor. The transistor t2 is a PNP bipolar transistor. The collector of the transistor t1 is connected to a positive power supply VCC. The emitter of the transistor t1 is connected to the first end of the resistor r1. The emitter of the transistor t2 is connected to the first end of the resistor r2. The collector of the transistor t2 is connected to a negative power supply VEE. Both the second ends of the resistors r1 and r2 are connected to an output end for an output signal Vout.

The output stage 5 generates the output signal Vout corresponding to the high-side signal and the low-side signal.

### <Macro Model>

The macro model for simulating the function of the semiconductor integrated circuit device 2 described above (more specifically, the output current Iout of the semiconductor integrated circuit device 2) will then be described in detail. The macro model Y will first be described as a comparative example of the macro model X of the present disclosure (=configuration compared with the embodiment of the present disclosure which will be described later) with reference to FIG. 3.

### <Macro Model Y of Comparative Example>

The macro model Y is a SPICE (Simulation Program with Integrated Circuit Emphasis) model in accordance with a nodal method.

FIG. 3 is a block diagram showing the configuration of the macro model Y. As shown in FIG. 3, the macro model Y includes a behavior model a1, a Zo calculation unit 7y, a behavior model a2 and a behavior model a3. The behavior models a1 to a3 and the Zo calculation unit 7y (more specifically, a conditional branch model ify1, a conditional branch model ify2, a conditional branch model ify3 and behavior models a4 to a14 which will be described later) are connected to each other via nodes.

The behavior model a1 calculates a difference between the output current Iout and an input current Iin, and inputs the result of the calculation to the Zo calculation unit 7y and the behavior model a2. The output current Iout is fed back to the behavior model a1.

The Zo calculation unit 7y calculates an impedance Zo based on the output values of I1, I2, I3 and I4, and inputs the result of the calculation to the behavior model a2 and the behavior model a3. The details of the Zo calculation unit 7y will be described later.

The behavior model a2 calculates the output current Iout based on the impedance Zo and the input current Iin. The behavior model a3 calculates a drive current Idout based on the output value of the behavior model a1 and the impedance Zo.

The Zo calculation unit 7y includes the conditional branch model ify1, the conditional branch model ify2, the conditional branch model ify3 and the behavior models a4 to a14.

The conditional branch model ify1 includes a node L1, a node R1, a node T1, a node F1 and a node O1. A ground end is connected to the node L1. In other words, a value of 0 is input to the node L1. The output end of the behavior model a1 is connected to the node R1. The node O2 of the conditional branch model ify2 is connected to the node T1. The node O3 of the conditional branch model ify3 is connected to the node F1. The node O1 is connected to the behavior models a2 and a3.

The conditional branch model ify2 includes a node L2, a node R2, a node T2, a node F2 and the node O2. The output end of the behavior model a4 is connected to the node L2. The output end of the behavior model a5 is connected to the node R2. The output end of the behavior model a6 is connected to the node T2. The output end of the behavior model a7 is connected to the node F2. The node O2 is connected to the node T1 of the conditional branch model ify1.

The conditional branch model ify3 includes a node L3, a node R3, a node T3, a node F3 and the node O3. The output end of the behavior model a10 is connected to the node L3. The output end of the behavior model a11 is connected to the node R3. The output end of the behavior model a12 is connected to the node T3. The output end of the behavior model a13 is connected to the node F3. The node O3 is connected to the node F1 of the conditional branch model ify1.

When an input value (in the present figure, a value of 0) which is input to the node L1 is greater than an input value (in FIG. 3, the output value of the behavior model a1) which is input to the node R1, the conditional branch model ify1 outputs an input value (in FIG. 3, the output value of the conditional branch model ify2) which is input to the node T1. By contrast, when the input value which is input to the node L1 is equal to or less than the input value which is input to the node R1, the conditional branch model ify1 outputs an input value (in FIG. 3, the output value of the conditional branch model ify3) which is input to the node F1.

When an input value (in the present figure, the output value of the behavior model a4) which is input to the node L2 is greater than an input value (in FIG. 3, the output value of the behavior model a5) which is input to the node R2, the conditional branch model ify2 outputs an input value (in FIG. 3, the output value of the behavior model a6) which is input to the node T2. By contrast, when the input value which is input to the node L2 is equal to or less than the input value which is input to the node R2, the conditional branch model ify2 outputs an input value (in FIG. 3, the output value of the behavior model a7) which is input to the node F2.

The behavior model a9 calculates the absolute value of the output value of the behavior model a1, and inputs the result of the calculation to the behavior model a4 and the behavior model a10. The behavior model a4 outputs a calculation result obtained by dividing the output value of the behavior model a9 by the output value of the behavior model a7. The behavior model a7 outputs a calculation result obtained by multiplying the output value of the behavior model a8 by a gain value (here, 100). The behavior model a8 calculates and outputs the absolute value of the output value of the I1.

The behavior model a5 calculates and outputs the absolute value of the I2. The behavior model a6 outputs a calculation result obtained by multiplying the output value of the behavior model a7 by maglimit (predetermined parameter value).

When an input value (in the present figure, the output value of the behavior model a10) which is input to the node L3 is greater than an input value (in FIG. 3, the output value of the behavior model a11) which is input to the node R3, the conditional branch model ify3 outputs an input value (in FIG. 3, the output value of the behavior model a12) which is input to the node T3. By contrast, when the input value which is input to the node L3 is equal to or less than the input value which is input to the node R3, the conditional branch model ify3 outputs an input value (in FIG. 3, the output value of the behavior model a13) which is input to the node F3.

The behavior model a10 outputs a calculation result obtained by dividing the output value of the behavior model a9 by the output value of the behavior model a13. The behavior model a11 calculates and outputs the absolute value of the output value of the I4. The behavior model a13 calculates and outputs a value obtained by multiplying the result of the output of the behavior model a13 by maglimit.

The behavior model a13 outputs a result obtained by multiplying the output of the behavior model a14 by a gain value (here, 100). The behavior model a14 calculates and outputs the absolute value of the output value of the I3.

### <Convergence Problem>

Incidentally, in the simulation performed with the macro model as described above, convergence is problematic. The convergence problem refers to a problem in which even when a simulation is performed, a calculation result does not converge to the desired result. Specifically, for example, a simulation analysis error occurs to prevent the start of a calculation or to stop a calculation halfway, with the result that the result of the calculation may be unstable.

In particular, in a macro model constructed in accordance with the nodal method, when the model includes a feedback path or when there is a discontinuous node, the convergence problem easily occurs. Furthermore, when there is a discontinuous node, a logical inconsistency easily occurs, and thus a simulation result (calculation result) may not converge. An example of the discontinuous node is a node which is included in a conditional branch. When a so-called model based development (MBD) is performed using the macro model including the discontinuous node as described above, the convergence problem easily occurs.

The macro model Y described above is configured by connecting a plurality of behavior models in accordance with the nodal method. The behavior model a1 receives the output current Iout as a feedback input, and thus a feedback path in the macro model Y is configured. Furthermore, the output end of the behavior model a1 is directly connected to the discontinuous node L1. The output end of the behavior model a1 is also connected to the discontinuous node L2 via the behavior models a9 and a4. Furthermore, the output end of the behavior model a1 is also connected to the discontinuous node L3 via the behavior models a9 and a10. As described above, the Zo calculation unit 7y is configured to calculate the impedance Zo by repeatedly passing through any one of the discontinuous nodes L1 to L3. Then, the convergence problem described above easily occurs.

By contrast, the macro model X according to the present disclosure can suppress the occurrence of the convergence problem. The macro model X according to the embodiment of the present disclosure will be described in detail below. The macro model X according to the embodiment of the present disclosure includes the same configurations as the macro model Y described above. Hence, the same configurations are identified with the same symbols, and the description thereof is omitted.

### <Macro Model X According to Embodiment>

The macro model X is a SPICE model in accordance with the nodal method.

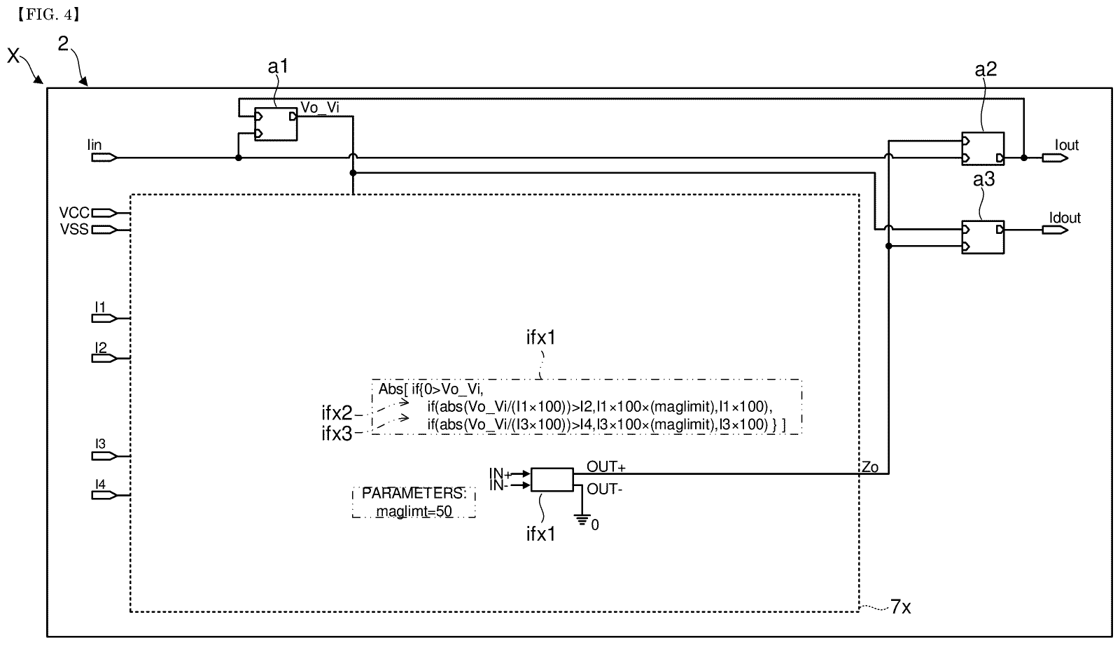

FIG. 4 is a block diagram showing the configuration of the macro model X. As shown in FIG. 4, the macro model X includes a Zo calculation unit 7x and behavior models a1 to a3. The Zo calculation unit 7x is a behavior model the function of which (more specifically, the function of calculating the impedance Zo) is simulated by one conditional branch (first conditional branch ifx1). The Zo calculation unit 7x is defined by formula (1) below.

$$\begin{matrix}[ Mathematical formula 1 ] & \\ abs [ {if}_{x 1} \{ 0 > {V}_{o -} {V}_{i} , {if}_{x 2} ( abs ( \frac{{V}_{o -} {V}_{i}}{I 1 \times 100} ) > I 2 , I 1 \times 100 \times maglimit , I 1 \times 100 ) , {if}_{x 3} ( abs ( \frac{{V}_{o -} {V}_{i}}{I 3 \times 100} ) > I 4 , I 3 \times 100 \times maglimit , I 3 \times 100 ) \} ] & ( 1 )\end{matrix}$$

As shown in formula (1), the calculation formula for the Zo calculation unit 7x is defined by one conditional branch (in FIG. 4, the first conditional branch ifx1) which includes a plurality of conditional branches (in FIG. 4, two conditional branches which are a second conditional branch ifx2 and a third conditional branch ifx3). Here, the most highly-defined conditional branch in formula (1) is set as the first conditional branch ifx1. Among the options of the first conditional branch ifx1, the conditional branch which is selected when the first conditional branch ifx1 is true is set as the second conditional branch ifx2. Among the options of the first conditional branch ifx1, the conditional branch which is selected when the first conditional branch ifx1 is false is set as the third conditional branch ifx3.

As shown in FIG. 4 and formula (1), the first conditional branch ifx1 determines whether the first conditional branch ifx1 is true or false based on the output Vo_Vin (first input) of the behavior model a1. As described previously, the value of the output Vo_Vin is a differential value between the output current Iout and the input current Iin.

Whether the second conditional branch ifx2 is true or false is determined based on the output Vo_Vin, the I1 (second input) and the I2 (third input). Among the options of the second conditional branch ifx2, a formula (=I1×100×maglimit) which is selected when the second conditional branch ifx2 is true is referred to as a first formula. Among the options of the second conditional branch ifx2, a formula which is selected when the second conditional branch ifx2 is false is referred to as a second formula (=I1×100).

The third conditional branch ifx3 determines whether the third conditional branch ifx3 is true or false based on an output Vo_Vi, the I3 (fourth input) and the I4 (fifth input). Among the options of the third conditional branch ifx3, a formula (=I3×100×maglimit) which is selected when the third conditional branch ifx3 is true is referred to as a third formula. Among the options of the third conditional branch ifx3, a formula (=I3×100) which is selected when the third conditional branch ifx3 is false is referred to as a fourth formula.

The first conditional branch ifx1 will be specifically described. When the value of the output Vo_Vi is negative, among the options of the first conditional branch ifx1 (either of the second conditional branch ifx2 and the third conditional branch ifx3), the second conditional branch ifx2 is selected. Here, when the output current Iout is greater than the I2 (more specifically, when Vo_Vi/(I1×100) is greater than the I2), among the options of the second conditional branch ifx2 (either of the first formula and the second formula), the first formula is selected. In this case, the impedance Zo is a value obtained by calculating the absolute value of I1×100×maglimit.

When the value of the output Vo_Vi is negative, and the output current Iout is equal to or less than the I2 (more specifically, when Vo_Vi/(I1×100) is equal to or less than the I2), among the options of the second conditional branch ifx2, the second formula is selected. In this case, the impedance Zo is a value obtained by calculating the absolute value of I1×100.

On the other hand, when the value of the output Vo_Vi is positive, among the options of the first conditional branch ifx1, the third conditional branch ifx3 is selected. Here, when the output current Iout is greater than the I4 (more specifically, when Vo_Vi/(I3×100) is greater than the I4), among the options of the third conditional branch ifx3 (either of the third formula and the fourth formula), the third formula is selected. In this case, the impedance Zo is a value obtained by calculating the absolute value of I3×100×maglimit.

When the value of the output Vo_Vi is positive, and the output current Iout is equal to or less than the I4 (more specifically, when Vo_Vi/(I3×100) is equal to or less than the I4), among the options of the third conditional branch ifx3, the fourth formula is selected. In this case, the impedance Zo is a value obtained by calculating the absolute value of I3×100.

As described previously, the Zo calculation unit 7x is configured with one behavior model (first conditional branch ifx1). Hence, a relatively small number of nodes are provided in the Zo calculation unit 7x, and thus the convergence problem is unlikely to occur.

As described previously, the Zo calculation unit 7x is configured with one behavior model (first conditional branch ifx1) which includes a plurality of conditional branches (the second conditional branch ifx2 and the third conditional branch ifx3) as options. Hence, the convergence problem is unlikely to occur.

The Zo calculation unit 7x selects one of calculation formulae of four patterns (one of the first to fourth formulae) according to the output current Iout to calculate the impedance Zo. Hence, it is possible to more accurately calculate the impedance Zo according to the output current Iout. Hence, the macro model X can perform a more accurate simulation while suppressing the convergence problem as described previously.

### <Circuit Design Simulator>

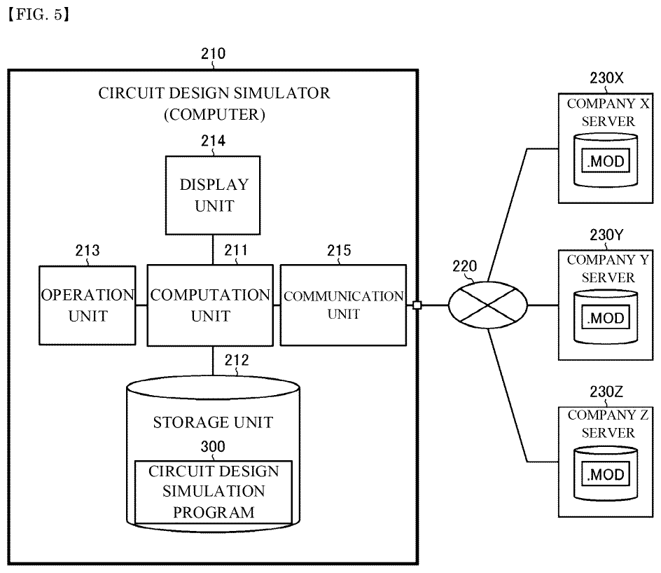

FIG. 5 is a block diagram showing a configuration example of a circuit design simulator using the macro model X described above. The circuit design simulator 210 in the present configuration example is a computer which includes a computation unit 211, a storage unit 212, an operation unit 213, a display unit 214 and a communication unit 215, and a circuit design simulation program 300 stored in the storage unit 212 is executed by the computation unit 211 to realize the circuit design simulator 210.

The computation unit 211 comprehensively controls the operation of the circuit design simulator 210. For example, the computation unit 211 executes the circuit design simulation program 300 stored in the storage unit 212 to perform various types of computation processing for achieving the function of the circuit design simulator 210, and also to perform recognition processing for a user operation input from the operation unit 213, display control for various types of screens on the display unit 214 and the like. As the computation unit 211, for example, a CPU (central processing unit) can be used.

The storage unit 212 is used as a storage region for an OS (operational system) program and various types of software (including the circuit design simulation program 300), and is also used as a storage region for various types of data generated by a user and an operation region for various types of software. As the storage unit 212, a hard disk drive, a solid state drive, a USB (universal serial bus) memory or the like can be used.

The operation unit 213 receives various types of user operations (such as a circuit generation operation, a component reference operation and a probe installation operation), and transmits them to the computation unit 211. As the operation unit 213, a keyboard, a mouse, a track ball, a pen tablet, a touch panel or the like can be used.

The display unit 214 displays various types of screens (such as a circuit generation field, a component pallet and a waveform drawing window) based on instructions from the computation unit 211. As the display unit 214, a liquid crystal display or the like can be used.

The communication unit 215 performs information communication via an electrical communication line 220 (such as the Internet or a LAN (local area network)) based on instructions from the computation unit 211. For example, the communication unit 215 performs information communication with the servers 230X to 230Z of vendors which manufacture and sell semiconductor integrated circuit devices via the electrical communication line 220, and downloads a macro model file (*.mod) and the like.

The circuit design simulator 210 as described above is used, and thus it is possible to perform simulation verification (such as a characteristic evaluation and an operation check) on an analog circuit before the analog circuit is actually fabricated as a prototype.

### <Circuit Design Simulation Program>

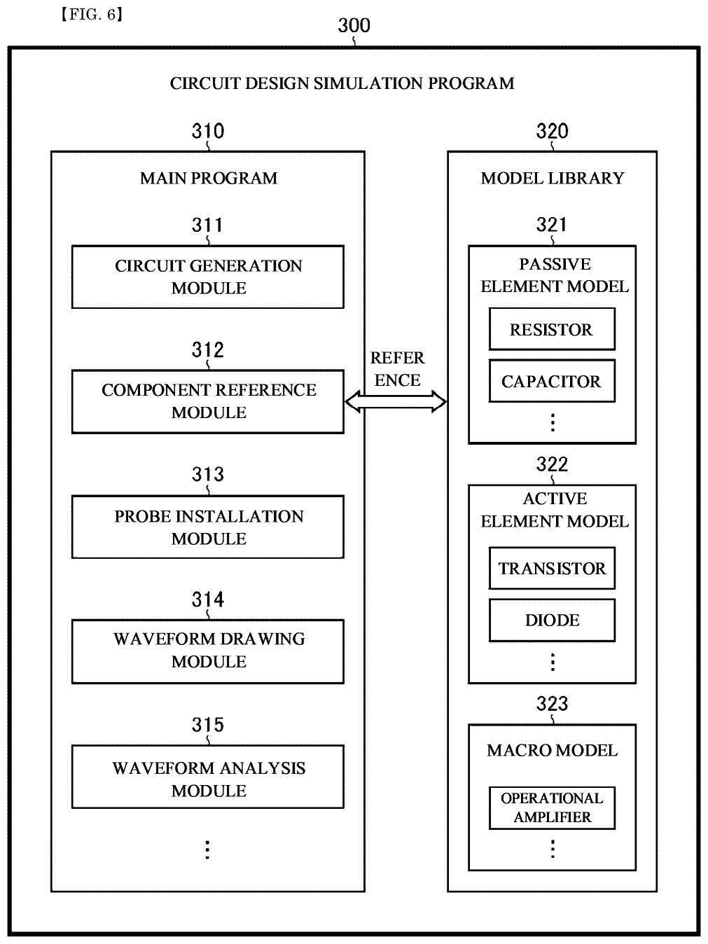

FIG. 6 is a diagram showing a configuration example of the circuit design simulation program 300. The circuit design simulation program 300 (for example, a SPICE-based circuit design simulation program) is software which is executed by a computer to cause the computer to function as the circuit design simulator 210 (see FIG. 5). The circuit design simulation program 300 in the present configuration example includes a main program 310 and a model library 320. The circuit design simulation program 300 is transferred or distributed via a physical medium such as an optical disc (such as a CD-ROM or a DVD-ROM) or a semiconductor memory (such as a USB memory) or via the electrical communication line such as the Internet.

The main program 310 is a core part for causing a computer to function as the circuit design simulator 210, and is formed as a collection of various types of module programs (for example, a circuit generation module 311, a component reference module 312, a probe installation module 313, a waveform drawing module 314 and a waveform analysis module 315).

The circuit generation module 311 is an element program for causing the computation unit 211 and the display unit 214 to function so as to generate a circuit on the circuit design simulator 210 based on an input from the operation unit 213. When the user uses the operation unit 213 to arrange, in the circuit generation field, component symbols (such as a resistor, a capacitor, a transistor, a diode, an operational amplifier, a voltage source, a current source and wiring) displayed on the display unit 214, the circuit generation module 311 generates a text-based code corresponding to the details of the arrangement. In this way, the user can intuitively generate an arbitrary analog circuit without directly editing the text-based code.

The component reference module 312 is an element program for causing the computation unit 211 and the display unit 214 to function so as to reference the model library 320 based on an input from the operation unit 213. For example, when the user uses the operation unit 213 to select the symbol of the operational amplifier from the component pallet displayed on the display unit 214, the component reference module 312 references a macro model 323 (which corresponds to the macro model X described previously) for the operational amplifier included in the model library 320.

The probe installation module 313 is an element program for causing the computation unit 211 and the display unit 214 to function so as to install a probe (measurement point for a voltage or current) on a circuit diagram based on an input from the operation unit 213. For example, when the user uses the operation unit 213 to click, with a mouse, a specific node on the circuit diagram displayed on the display unit 214, the probe installation module 313 installs a probe on the clicked node.

The waveform drawing module 314 is an element program for causing the computation unit 211 and the display unit 214 to function so as to draw the waveform of a node on which a probe is installed based on an input from the operation unit 213. For example, when the user uses the operation unit 213 to install a probe on the output terminal of the operational amplifier displayed on the display unit 214, the waveform drawing module 314 displays the output waveform (pseudo-oscilloscope waveform) of the operational amplifier on the waveform drawing window.

The waveform analysis module 315 is an element program for causing the computation unit 211 and the display unit 214 to function so as to perform a waveform analysis on a node on which a probe is installed based on an input from the operation unit 213. Examples of the waveform analysis which can be performed by the waveform analysis module 315 include a transient analysis, a direct-current analysis, a small-signal alternating-current analysis, a noise analysis and the like.

The model library 320 includes various simulation models (such as a passive element model 321, an active element model 322 and the macro model 323) used in the circuit design simulator 201, and is referenced as one component of the circuit design simulation program 300 by the main program 310 (in particular, the component reference module 312). The passive element model 321 is a program which operates a computer so as to simulate the response of passive elements (such as a resistor and a capacitor) on the circuit design simulator 210. The active element model 322 is a program which operates a computer so as to simulate the response of active elements (such as a transistor and a diode) on the circuit design simulator 210. The macro model 323 (which corresponds to the macro model X described previously) for the operational amplifier is a program which operates a computer so as to simulate the response of the operational amplifier on the circuit design simulator 210. The simulation models (the passive element model 321, the active element model 322 and the macro model 323) described above include a simulation model which can be downloaded free of charge from the servers 230X to 230Z of vendors which manufacture and sell semiconductor integrated circuit devices via the electrical communication line 220.

The circuit design simulation program 300 as described above is used, and thus a general-purpose computer (such as a personal computer or a workstation) can be utilized as the circuit design simulator 210.

### <Other Variations>

In addition to the embodiment described above, various technical features disclosed in the present specification can be changed in various ways without departing from the spirit of its technical creation. In other words, the embodiment described above should be considered to be illustrative in all respects, and not restrictive, the technical scope of the present invention is not limited to the embodiment described above and meanings equivalent to the scope of claims and all changes within the scope should be understood to be included therein.

For example, the first to fourth formulae described above may include a conditional branch as an option. In this way, various functions can be defined by one behavior model. Hence, a macro model configured with a relatively small number of nodes is used, and thus it is possible to highly simulate a relatively complicated function while suppressing the convergence problem described previously.

Although the macro model X is assumed to be a SPICE model in accordance with the nodal method, as long as the macro model X is a simulation model using a method in accordance with the nodal method, the macro model X is not limited to the SPICE model and may be another simulation model.

The Zo calculation unit 7x can be configured to include another behavior model instead of the first conditional branch ifx1. In this way, it is possible to provide the macro model X which can perform a more sophisticated simulation.

An electronic component which is a simulation target for the macro model X described above is not limited to the operational amplifier described above, and may be another semiconductor integrated circuit device.

### <<Additional Description>>

The macro model (X) disclosed in the specification is a macro model (X) that is used in a circuit design simulator (210) based on a nodal method, and the macro model (X) is configured to include a behavior model (7x) the function of which is defined by one conditional branch (ifx1) that includes a plurality of conditional branches (ifx2 and ifx3) as options (first configuration).

Preferably, in the macro model (X) according to the first configuration, the behavior model (7x) includes a first conditional branch (ifx1) that determines whether the first conditional branch (ifx1) is true or false, a second conditional branch (ifx2) that is selected when the first conditional branch (ifx1) is true and a third conditional branch (ifx3) that is selected when the first conditional branch (ifx1) is false, the second conditional branch (ifx2) is configured to include a first formula that is selected when the second conditional branch (ifx2) is true and a second formula that is selected when the second conditional branch (ifx2) is false and the third conditional branch (ifx3) is configured to include a third formula that is selected when the third conditional branch (ifx3) is true and a fourth formula that is selected when the third conditional branch (ifx3) is false (second configuration).

Preferably, in the macro model (X) according to the second configuration, the first conditional branch (ifx1) is defined to determine whether the first conditional branch (ifx1) is true or false based on a first input (Vo_Vi), the second conditional branch (ifx2) is defined to determine whether the second conditional branch (ifx2) is true or false based on the first input (Vo_Vi), a second input (I1) and a third input (I2), the third conditional branch (ifx3) is defined to determine whether the third conditional branch (ifx3) is true or false based on the first input (Vo_Vi), a fourth input (I3) and a fifth input (I4), the first formula is a calculation formula based on the second input (I1) and a predetermined parameter value (maglimit), the second formula is a calculation formula based on the second input (I1), the third formula is a calculation formula based on the fourth input (I3) and the parameter value (maglimit) and the fourth formula is a calculation formula based on the fourth input (I3) (third configuration).

Preferably, in the macro model (X) according to any one of the first to third configurations, the behavior model (7x) is configured to receive a feedback input corresponding to the output (Iout) of the behavior model (fourth configuration).

Preferably, in the macro model (X) according to the fourth configuration, the macro model is configured to simulate the function of an operational amplifier (fifth configuration).

The circuit design simulation program (300) disclosed in the specification is a circuit design simulation program (300) configured to be executed by a computer including a computation unit and to cause the computer to function as the circuit design simulator (210), the circuit design simulation program includes the macro model (X) according to any one of the first to fifth configurations and the circuit design simulation program is configured to operate the computer such that the response of a semiconductor integrated circuit device (2) is simulated on the circuit design simulator (210) (sixth configuration).

The circuit design simulator (210) disclosed in the specification is configured to be realized by causing the computer to execute the circuit design simulation program (300) according to the sixth configuration (seventh configuration).

In the macro model (X) of the first configuration, the macro model (X) in which a plurality of conditional formulae are included in the options (ifx2 and ifx3) of the conditional branch (ifx1) can be defined. Hence, it is possible to reduce the number of nodes to define a more complicated calculation formula. In this way, it is possible to configure the macro model (X) which can perform a more sophisticated simulation while suppressing the convergence problem.

In the macro model (X) of the second configuration, it is possible to perform a more sophisticated simulation while suppressing the convergence problem.

In the macro model (X) of the third configuration, the predetermined parameter value (maglimit) is defined, and thus it is possible to configure the macro model (X) which corresponds to various simulations.

In the macro model (X) of the fourth configuration, it is possible to suppress the convergence problem in the macro model (X) which simulates a control circuit including feedback control.

In the macro model (X) of the fifth configuration, it is possible to suppress the convergence problem in the macro model (X) which simulates the function of the operation amplifier.

In the circuit design simulation program (300) of the sixth configuration, it is possible to perform simulation verification on an analog circuit before the analog circuit is actually fabricated as a prototype.

In the circuit design simulator (210) of the seventh configuration, a general-purpose computer can be utilized as the circuit design simulator (210).

What is claimed is:

1. A macro model that is used in a circuit design simulator based on a nodal method,
wherein the macro model is configured to include a behavior model a function of which is defined by one conditional branch that includes a plurality of conditional branches as options.

2. The macro model according to claim 1,
wherein the behavior model includes
a first conditional branch that determines whether the first conditional branch is true or false,
a second conditional branch that is selected when the first conditional branch is true and
a third conditional branch that is selected when the first conditional branch is false,
the second conditional branch is configured to include
a first formula that is selected when the second conditional branch is true and
a second formula that is selected when the second conditional branch is false and
the third conditional branch is configured to include
a third formula that is selected when the third conditional branch is true and
a fourth formula that is selected when the third conditional branch is false.

3. The macro model according to claim 2,
wherein the first conditional branch is defined to determine whether the first conditional branch is true or false based on a first input,
the second conditional branch is defined to determine whether the second conditional branch is true or false based on the first input, a second input and a third input,
the third conditional branch is defined to determine whether the third conditional branch is true or false based on the first input, a fourth input and a fifth input,
the first formula is a calculation formula based on the second input and a predetermined parameter value,
the second formula is a calculation formula based on the second input,
the third formula is a calculation formula based on the fourth input and the parameter value and
the fourth formula is a calculation formula based on the fourth input.

4. The macro model according to claim 1,
wherein the behavior model is configured to receive a feedback input corresponding to an output of the behavior model.

5. The macro model according to claim 4,
wherein the macro model is configured to simulate a function of an operational amplifier.

6. A circuit design simulation program configured
to be executed by a computer including a computation unit and
to cause the computer to function as the circuit design simulator,
wherein the circuit design simulation program includes the macro model according to claim 1, and
the circuit design simulation program operates the computer such that a response of a semiconductor integrated circuit device is simulated on the circuit design simulator.

7. A circuit design simulator that is realized by causing the computer to execute the circuit design simulation program according to claim 6.
